(19) United States
(12) Patent Application Publication
(10) Pub. No.: US 2020/0161784 A1
(43) Pub. Date: May 21, 2020

(54) CIRCUIT DEVICE

(71) Applicants: AutoNetworks Technologies, Ltd., Yokkaichi-shi, Mie (JP); Sumitomo Wiring Systems, Ltd., Yokkaichi-shi, Mie (JP); SUMITOMO ELECTRIC INDUSTRIES, LTD., Osaka-shi, Osaka (JP)

(72) Inventors: Hirokazu Komori, Yokkaichi-shi, Mie (JP); Hiroki Hirai, Yokkaichi-shi, Mie (JP); Hirokazu Eguchi, Itami-shi, Hyogo (JP)

(21) Appl. No.: 16/626,595

(22) PCT Filed: Jun. 27, 2018
(86) PCT No.: PCT/JP2018/024278

§ 371 Date: Dec. 26, 2019

(30) Foreign Application Priority Data
Jul. 4, 2017 (JP) 2017-131186

(51) Int. Cl. H01R 12/71; H01R 13/52; H05K 1/02; H01R 43/02; H01R 12/55

(52) U.S. Cl. CPC H01R 12/71; H01R 13/5216; H01R 12/55; H01R 43/0256; H05K 1/02

(57) ABSTRACT

An ECU 1 includes a circuit board 10, a connector 20 fixed to the circuit board 10, a resin portion 50 covering the circuit board 10 and the connector 20. A buffer portion 60 is interposed between the circuit board 10 and the connector 20, between the circuit board 10 and the resin portion 50, or between the connector 20 and the resin portion 50. This configuration enables the buffer portion 60 having elasticity to absorb the stresses generated due to differences in linear expansion coefficient in the boundary portion between the circuit board 10 and the connector 20, the boundary portion between the circuit board 10 and the resin portion 50, and the boundary portion between the connector 20 and the resin portion 50. This makes it possible to prevent the connector 20 from peeling from the circuit board 10.

### BACKGROUND

Field of the Invention

The technology disclosed in this specification relates to a circuit device.

Related Art

A structure in which an entire circuit board and a portion fixed to the circuit board through a connector are covered with a mold resin is known as a waterproof structure for a circuit device including a circuit board and a connector fixed to the circuit board (see Japanese Unexamined Patent Application Publication No. 2010-40992).

Materials used for a circuit board, a connector, and a mold resin differ in linear expansion coefficient from each other. Accordingly, a heat history may cause distortion of the circuit board and peeling of the connector from the circuit board.

### SUMMARY

A circuit device disclosed in this specification is a circuit device including a circuit board, a connector fixed to the circuit board, and a resin portion covering the circuit board and the connector. A buffer portion formed from a material having elasticity is interposed between the circuit board and the connector, between the circuit board and the resin portion, or between the connector and the resin portion.

According to the above configuration, the elastic buffer portion can absorb the stress generated by differences in linear expansion coefficient in a boundary portion between the circuit board and the connector, a boundary portion between the circuit board and the resin portion, or a boundary portion between the connector and the resin portion. This makes it possible to prevent the connector from peeling from the circuit board.

In the above configuration, the connector may include a connector housing and a metal member fixed to the connector housing and the circuit board, and the buffer portion may be interposed between the metal member and the resin portion.

According to this configuration, the buffer portion can absorb stress around the metal member fixed to the circuit board. This can further effectively prevent the connector from peeling from the circuit board.

The metal member may be a fixing fitting or terminal fitting for fixing the connector housing to the circuit board.

The circuit device disclosed in this specification can prevent the connector from peeling from the circuit board.

### BRIEF DESCRIPTION OF THE DRAWINGS

FIG. 1 is a plan view of an ECU according to an embodiment.

FIG. 2 is a sectional view taken along line A-A in FIG. 1.

FIG. 3 is a perspective view of a connector according to the embodiment.

FIG. 4 is a plan view of the connector according to the embodiment.

FIG. 5 is a sectional view taken along line B-B in FIG. 4.

FIG. 6 is a perspective view of a circuit board to which the connector is fixed according to the embodiment.

FIG. 7 is a plan view of the circuit board to which the connector is fixed.

FIG. 8 is a sectional view taken along line C-C in FIG. 7.

FIG. 9 is an enlarged view of the interior of a circle R in FIG. 7.

FIG. 10 is a plan view of a primary molded product according to the embodiment.

FIG. 11 is a sectional view taken along line D-D in FIG. 10.

FIG. 12 is a sectional view of an ECU according to a modification taken at the same position as line D-D in FIG. 10.

### DETAILED DESCRIPTION

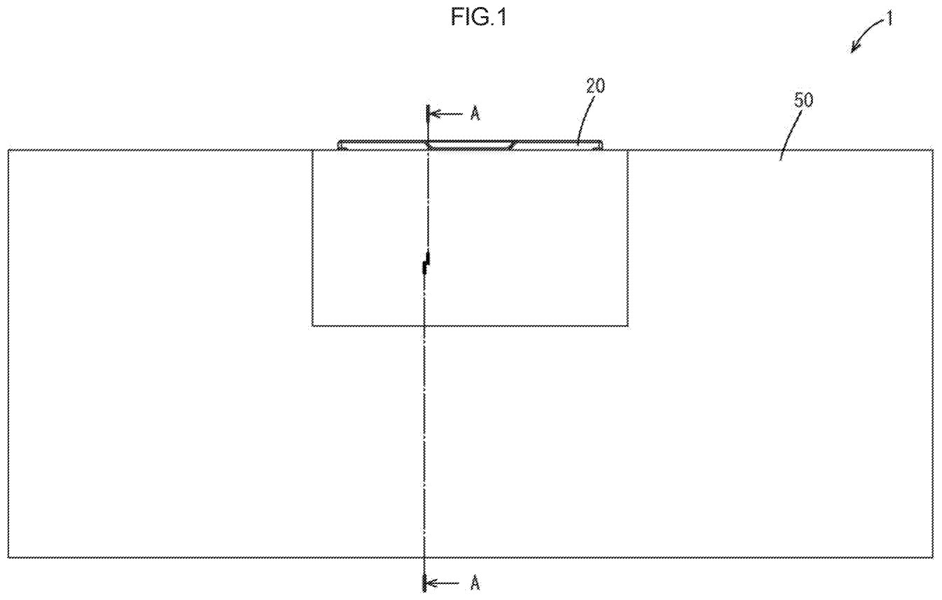

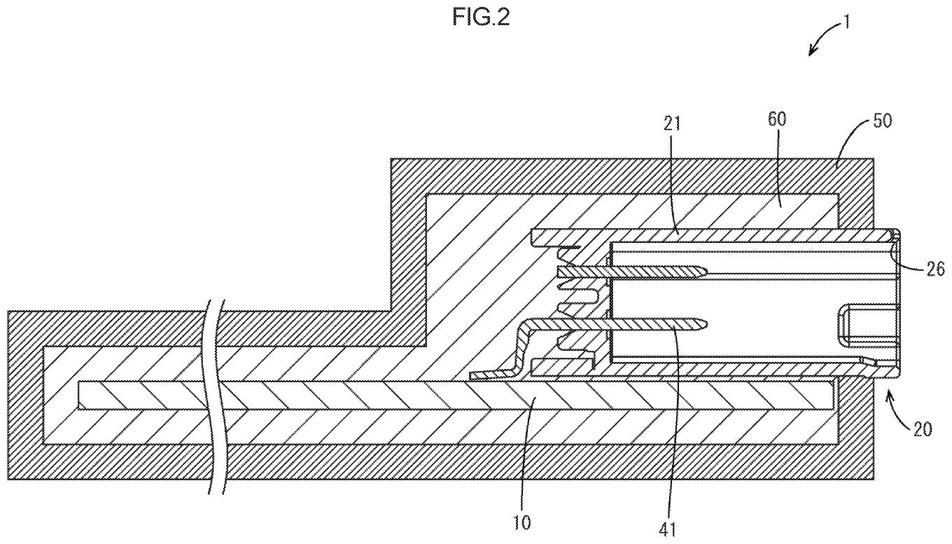

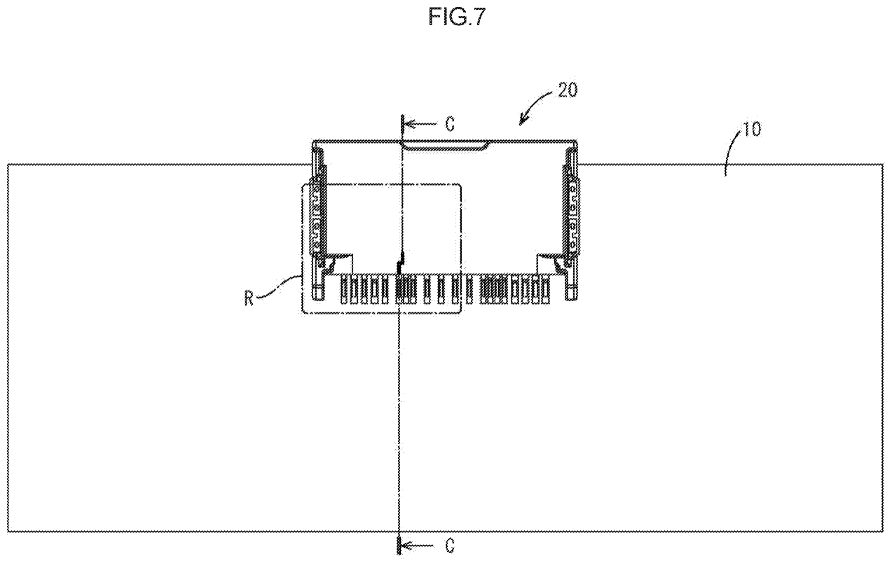

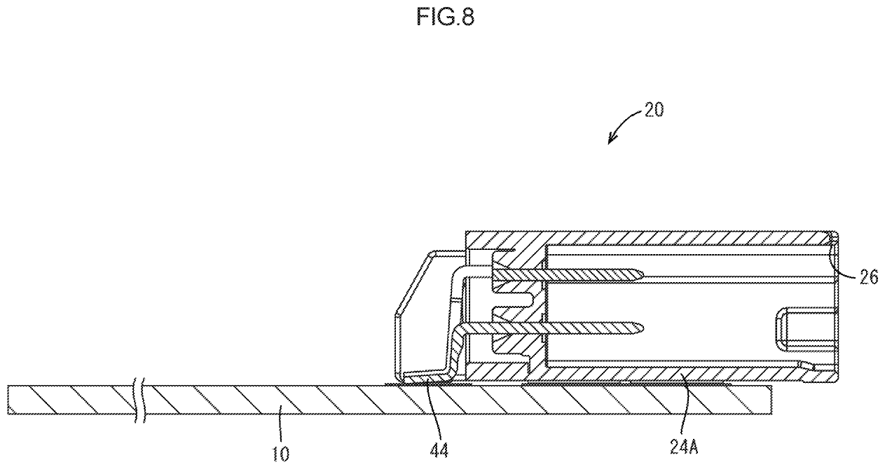

An embodiment will be described with reference to FIGS. 1 to 11. A circuit device according to this embodiment is an electronic control unit (ECU) 1 disposed in a wheel house of a vehicle in an electric brake system and configured to control braking. As shown in FIG. 2, the ECU 1 includes a circuit board 10, a connector 20 fixed to one surface of the circuit board 10, a resin portion 50 made of a synthetic resin that covers the circuit board 10 and the connector 20, and a buffer portion 60 interposed between the circuit board 10 and the connector 20, between the circuit board 10 and the resin portion 50, and between the connector 20 and the resin portion 50.

The circuit board 10 is a member having a known configuration, which has electrically conducting paths (not shown) formed by a printed wiring technique on one or both surfaces of an insulating plate made of an insulating material and on which electronic components (not shown) are mounted.

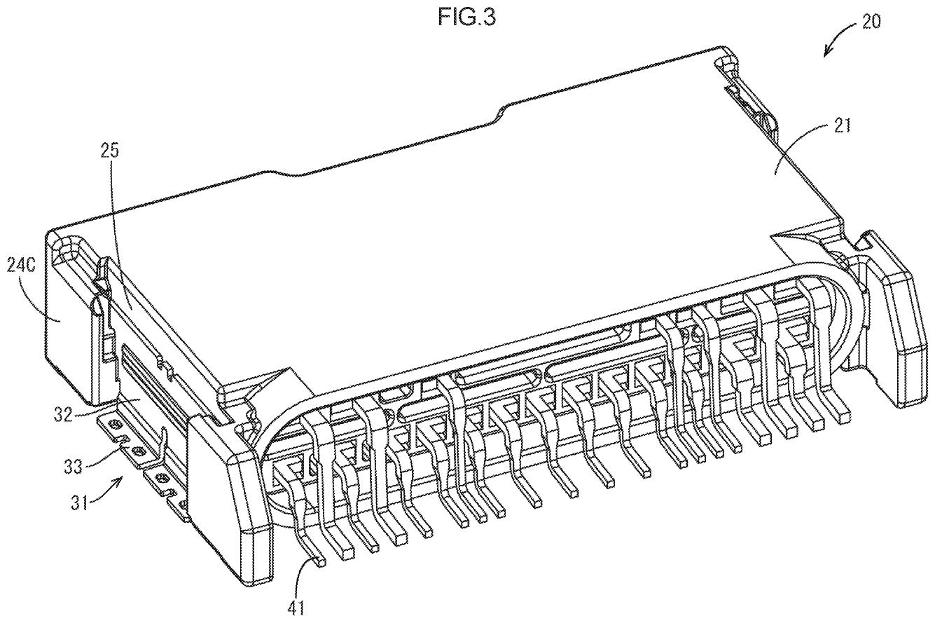

As shown in FIGS. 3 to 5, the connector 20 includes a connector housing 21, two fixing fittings 31 (corresponding to metal members) for fixing the connector housing 21 to the circuit board 10, and a plurality of terminal fittings 41 (corresponding to metal members) fixed to the connector housing 21 and connected to the electrically conducting paths on the circuit board 10.

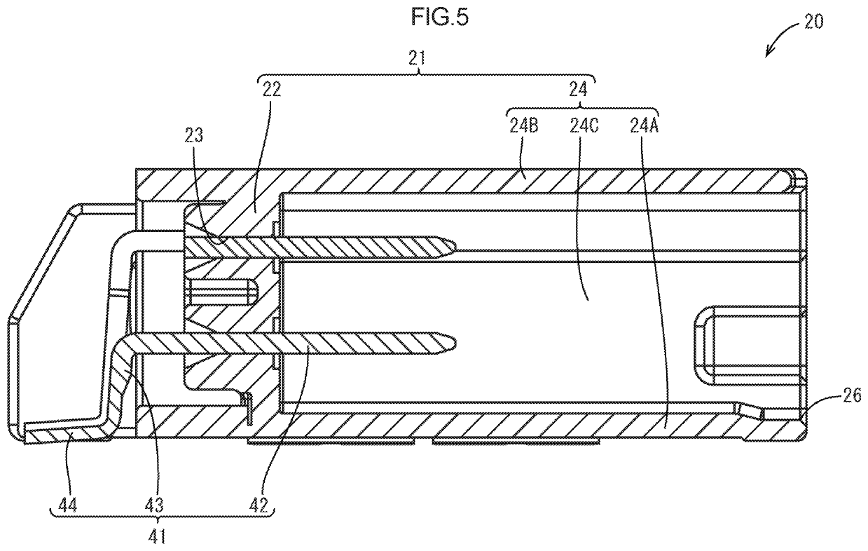

As shown in FIG. 5, the connector housing 21 is made of a synthetic resin and includes a terminal holding wall 22 and a hood portion 24 continuous from the terminal holding wall 22.

As shown in FIG. 5, the terminal holding wall 22 is a plate-like portion having a thickness enough to hold the terminal fittings 41 and includes a plurality of press fitting holes 23 into which the terminal fittings 41 can be press-fit. The hood portion 24 is a rectangular cylindrical portion extending from one surface of the terminal holding wall 22, and includes a bottom wall 24A disposed along the circuit board 10, a top wall 24B parallel to the bottom wall 24A, and two side walls 24C joining the bottom wall 24A to the top wall 24B, and has an opening portion 26 on the opposite side to the terminal holding wall 22. The internal space of the connector housing 21 surrounded by the terminal holding wall 22 and the hood portion 24 can accommodate a mating connector.

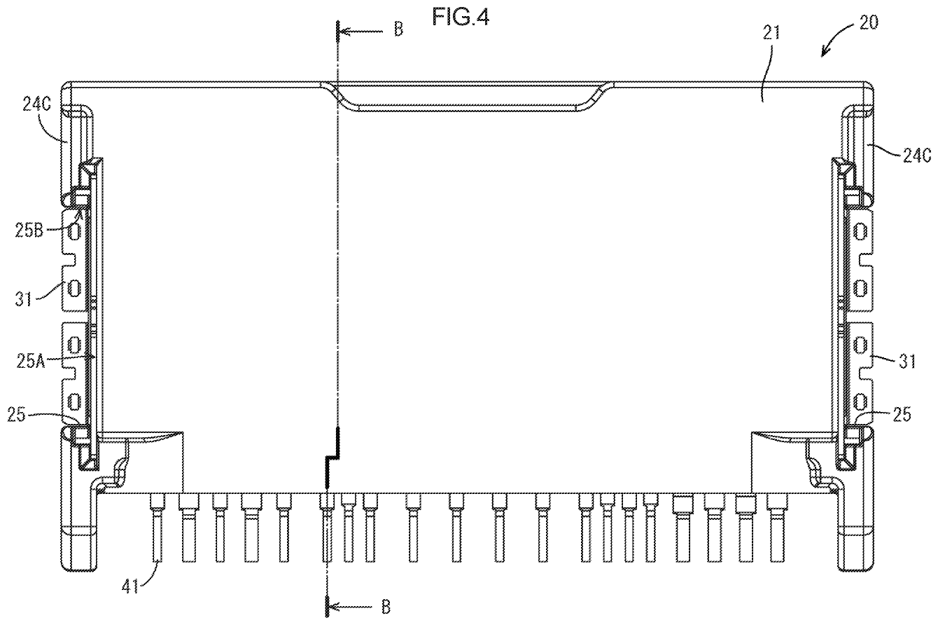

As shown in FIGS. 3 and 4, each of the two side walls 24C has a mounting groove 25. Each mounting groove 25 is a wide groove defined by a groove bottom surface 25A parallel to an outside surface of the side wall 24C and a pair of groove side surfaces 25B continuous from the groove bottom surface 25A and parallel to the terminal holding wall 22, and extends from top wall 24B to the bottom wall 24A.

Each of the two fixing fittings 31 is a member formed by pressing a metal plate material and has an L shape as a whole, including a substantially rectangular main body portion 32 and a mounting portion 33 in the form of a plate piece extending vertically from one side of the main body portion 32, as shown in FIG. 3. Although not shown in detail, a plurality of locking pieces are arranged on each of two side edges (two sides perpendicular to one side to which the mounting portion 33 is connected) of the main body portion 32, and engagement receiving portions with which the plurality of locking pieces engage are arranged on each of the pair of groove side surfaces 25B.

As shown in FIGS. 3 and 4, one fixing fitting 31 is accommodated in the mounting groove 25 disposed in one side wall 24C, and the other fixing fitting 31 is accommodated in the mounting groove 25 disposed in the other side wall 24C. Each fixing fitting 31 is disposed, with the main body portion 32 extending along the groove bottom surface 25A, and is held while being positioned, with the mounting portion 33 slightly protruding from the bottom wall 24A, by engaging the locking piece with the engagement receiving portion.

As shown in FIG. 5, each of the plurality of terminal fittings 41 is a member formed by bending an elongated metal plate material, and is constituted by a tab portion 42 press-fitted into the press fitting hole 23 and extending through terminal holding wall 22, an intermediate portion 43 extending substantially vertically from one end of the tab portion 42, and a board connecting portion 44 extending from an extending end of the intermediate portion in a direction opposite to the tab portion 42. The distal end portion of the tab portion 42 is disposed inside the hood portion 24. The intermediate portion 43 and the board connecting portion 44 are arranged outside the connector housing 21.

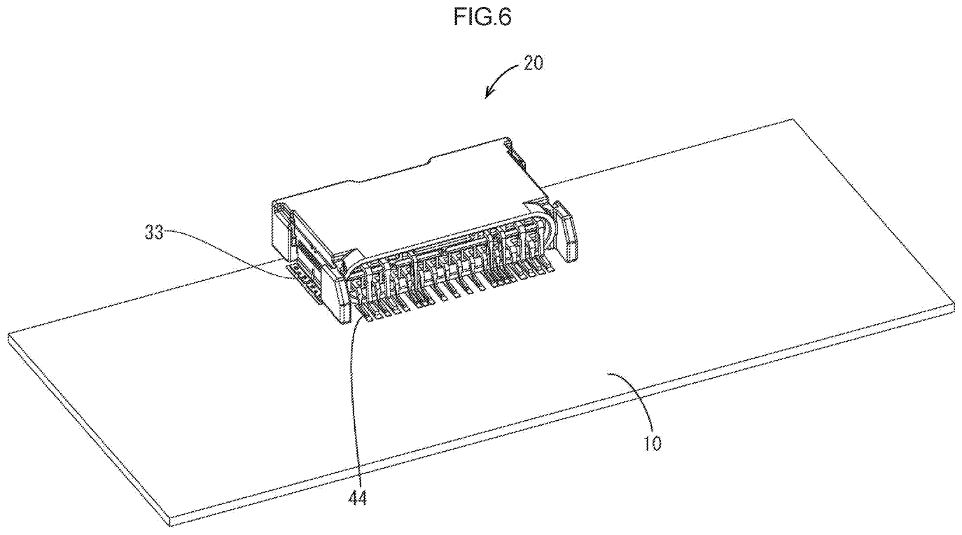

As shown in FIGS. 6 to 8, the connector 20 is fixed to the circuit board 10 such that the bottom wall 24A is directed to face the circuit board 10, and a portion of the hood portion 24 which is adjacent to the opening portion 26 protrudes from an end edge of the circuit board 10 by a predetermined dimension. The connector 20 is fixed to the circuit board 10 by disposing the mounting portion 33 along the circuit board 10 and fixing the mounting portion 33 to the circuit board 10 by reflow soldering. While connector 20 is fixed to the circuit board 10, there is a slight gap between the bottom wall 24A and the circuit board 10. The board connecting portions 44 are arranged along the circuit board 10 and electrically connected to the electrically conducting paths by reflow soldering.

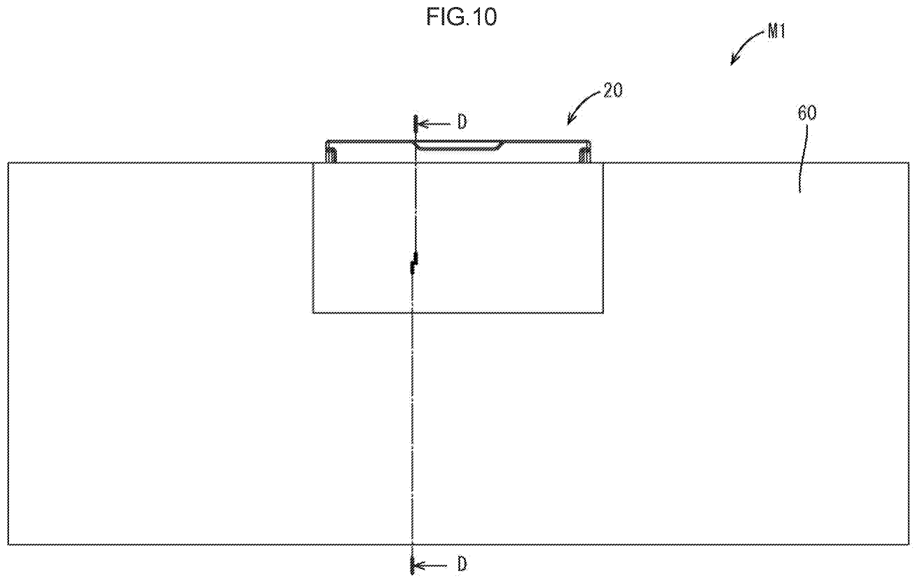

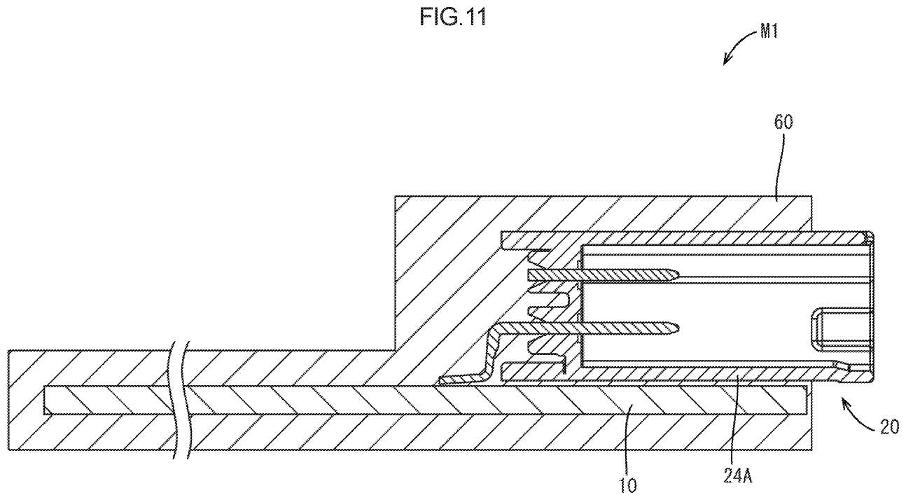

As shown in FIGS. 10 and 11, the buffer portion 60 is formed from a material having elasticity and insulation properties and covers the entire circuit board 10 and most of the connector 20 in a tight contact state. The circuit board 10 is entirely embedded in the buffer portion 60, whereas only a portion of the connector 20 which is adjacent to the opening portion 26 protrudes from the buffer portion 60, and the remaining portion is embedded in the buffer portion 60. Note that the buffer portion 60 is also disposed in the gap between the bottom wall 24A and the circuit board 10. Examples of preferable materials for the buffer portion 60 include olefin-based rubber such as ethylene-propylene rubber and styrene-based rubber such as styrene-butadiene rubber and styrene-butylene rubber.

As shown in FIGS. 1 and 2, the resin portion 50 covers the entire buffer portion 60 in a tight contact state. The circuit board 10 and the buffer portion 60 are entirely embedded in the resin portion 50, whereas only a portion of the connector 20 which is adjacent to the opening portion 26 protrudes from the resin portion 50, and the remaining portion is embedded in the resin portion 50. A hot-melt adhesive agent is an example of a preferable material for the resin portion 50.

The buffer portion 60 is interposed between the circuit board 10 and the resin portion 50, and between the connector 20 and the resin portion 50, and is also disposed in the gap between the bottom wall 24A and the circuit board 10, thus being also interposed between the circuit board 10 and the connector 20.

For example, the following is a procedure for manufacturing the ECU 1 having the above configuration.

First of all, the terminal fittings 41 and the fixing fittings 31 are fixed to the connector housing 21.

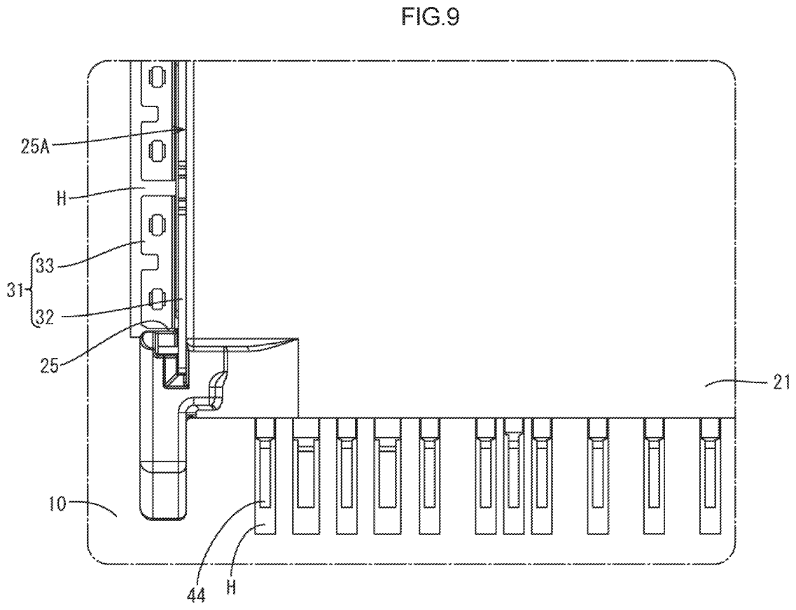

The connector 20 is then fixed to the circuit board 10 by reflow soldering. First of all, solder H is applied to each soldering target region on one surface of the circuit board 10 (see FIG. 9). Subsequently, the connector 20 is mounted on one surface of the circuit board 10 such that a portion of the hood portion 24 which is adjacent to the opening portion 26 protrudes from an end edge of the circuit board 10 by a predetermined dimension (see FIGS. 6 to 8). At this time, the board connecting portion 44 of each terminal fitting 41 is mounted on the solder H, and the mounting portion 33 of each fixing fitting 31 is also mounted on the solder H. The circuit board 10 on which the connector 20 is mounted is transported in a reflow furnace (not shown) to melt the solder H. When the solder H is cooled and solidified, the board connecting portion 44 of each terminal fitting 41 is fixed and rendered conductive to the corresponding electrically conducting path, and the mounting portion 33 of each fixing fitting 31 is fixed to the circuit board 10.

The buffer portion 60 and the resin portion 50 are then formed by two-step injection molding. First of all, the buffer portion 60 is formed by primary molding. The circuit board 10 to which the connector 20 is fixed is set in a mold (not shown). The mold is filled with heated plasticized rubber. The rubber is then vulcanized to obtain a primary molded product M1, with the circuit board 10, the connector 20, and the buffer portion 60 being integrated (see FIG. 11). Note that at this time, rubber also flows into the gap between the bottom wall 24A and the circuit board 10 to form the buffer portion 60.

The resin portion 50 is then formed by secondary molding. The primary molded product M1 is set in a mold (not shown), and the mold is filled with a melted resin. Subsequently, the filled resin and cooled and solidified to complete the ECU 1, with the resin portion 50 and the primary molded product M1 being integrated (see FIG. 2).

The materials used for the circuit board 10, the connector 20, and the resin portion 50 differ in linear expansion coefficient. For this reason, when the ECU 1 is equipped with a vehicle, a heat history may cause distortion of the circuit board 10 and peeling of the connector 20 from the circuit board 10 while the ECU 1 is used. Accordingly, in this embodiment, the buffer portion 60 is interposed between the circuit board 10 and the connector 20, between the circuit board 10 and the resin portion 50, and between the connector 20 and the resin portion 50. According to this configuration, the buffer portion 60 having elasticity can absorb the stresses generated in the boundary portion between the circuit board 10 and the connector 20, the boundary portion between the circuit board 10 and the resin portion 50, and the boundary portion between the connector 20 and the resin portion 50. This makes it possible to prevent the connector 20 from peeling from the circuit board 10.

In particular, the fixing fittings 31 and the terminal fittings 41 fixed to the connector housing 21 are fixed to the circuit board 10 by the solder H. The buffer portion 60 is interposed between the fixing fittings 31 and the resin portion 50 and between the terminal fittings 41 and the resin portion 50. More specifically, the portions (the mounting portions 33 and the board connecting portions 44) fixed to the circuit board 10 with the solder H are embedded in the buffer portion 60. This makes it possible to make the buffer portion 60 absorb the stresses generated by a heat history around the portions fixed with the solder H and effectively prevent the connector 20 from peeling from the circuit board 10.

As described above, according to this embodiment, the ECU 1 includes the circuit board 10, the connector 20 fixed to the circuit board 10, and the resin portion 50 covering the circuit board 10 and the connector 20, with the buffer portion 60 being interposed between the circuit board 10 and the connector 20, between the circuit board 10 and the resin portion 50, and between the connector 20 and the resin portion 50.

According to the above configuration, the buffer portion 60 having elasticity can absorb the stresses generated in the boundary portion between the circuit board 10 and the connector 20, the boundary portion between the circuit board 10 and the resin portion 50, and the boundary portion between the connector 20 and the resin portion 50 due to differences in linear expansion coefficient. This makes it possible to prevent the connector 20 from peeling from the circuit board 10.

The connector 20 includes the connector housing 21 and the fixing fittings 31 and the terminal fittings 41 fixed to the connector housing 21 and the circuit board 10. The buffer portion 60 is interposed between the fixing fittings 31 and the resin portion 50 and between the terminal fittings 41 and the resin portion 50.

According to this configuration, the buffer portion 60 can absorb stresses around the fixing fittings 31 and the terminal fittings 41 fixed to the circuit board 10. This can more effectively prevent the connector 20 from peeling from the circuit board 10.

### MODIFICATION

An ECU 70 according to this modification differs from the ECU according to the above embodiment in that a buffer portion 71 is interposed between the circuit board 10 and the connector 20 and between the connector 20 and the resin portion 50 but is not interposed between the resin portion 50 and a portion of the circuit board 10 excluding a peripheral portion of the connector 20.

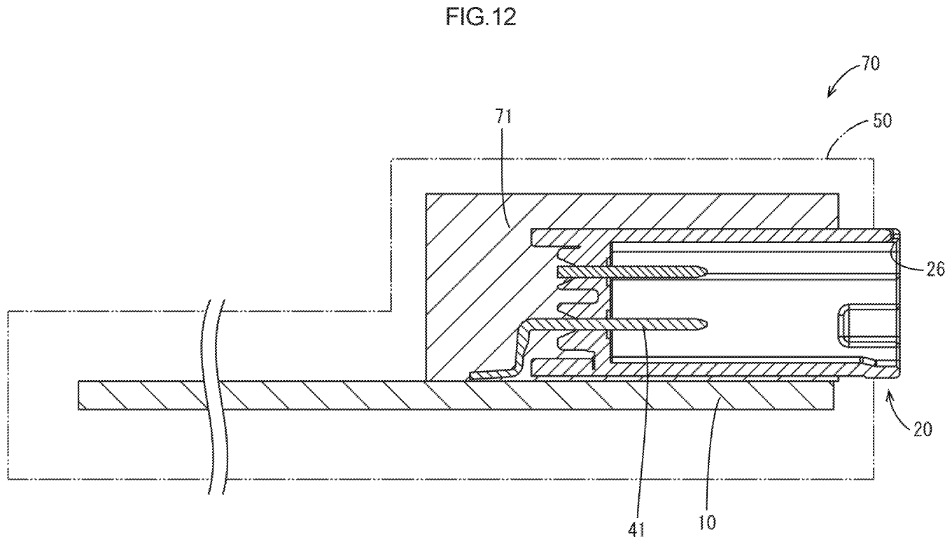

As shown in FIG. 12, the buffer portion 71 is disposed on one surface of the circuit board 10 and has a block-like outer shape one size larger than the connector 20. Only a portion of the connector 20 which is adjacent to the opening portion 26 protrudes from the buffer portion 71, and the remaining portion is embedded in the buffer portion 71. As in the embodiment, the buffer portion 71 is also disposed between the bottom wall 24A and the circuit board 10.

As described above, interposing the buffer portion 71 between the circuit board 10 and the connector 20 and between the connector 20 and the resin portion 50 makes it possible to obtain the effect of preventing the connector 20 from peeling from the circuit board 10.

### OTHER EMBODIMENTS

The technology disclosed in this specification is not limited to the embodiment described with reference to the above description and drawings, and includes, for example, the following aspects.

Interposing a buffer portion at least at one of a position between a circuit board and a connector, a position between the circuit board and a resin portion, or a position between the connector and the resin portion will obtain the effect of preventing the connector from peeling from the circuit board. In addition, even interposing the buffer portion between a portion of the connector and the circuit board, between a portion of the circuit board and the resin portion, or between a portion of the connector and the resin portion will obtain a certain effect of preventing the connector from peeling from the circuit board.

In the above embodiment, the buffer portion 60 is interposed between the fixing fittings 31 and the resin portion 50 and between the terminal fittings 41 and the resin portion 50. In contrast to this, interposing the buffer portion at least between the fixing fittings or the terminal fittings and the resin portion can obtain a certain effect of preventing the connector from peeling from the circuit board.

In the above embodiment, the connector 20 is embedded in the buffer portion 60 except for a portion of the connector 20 which is adjacent to the opening portion 26, and the entire fixing fittings 31 are embedded in the buffer portion 60. However, even interposing the buffer portion between portions of the fixing fittings and the resin portion can obtain the effect of preventing the connector from peeling from the circuit board. In this case, it is preferable to interpose a buffer portion at least between the resin portion and the portions fixed to the circuit board with solder. Similarly, for the terminal fittings, it is preferable to interpose the buffer portion between the resin portion and the portions fixed to the circuit board with solder.

### EXPLANATION OF SYMBOLS

1: ECU (circuit device)
10: circuit board
20: connector
50: resin portion
60, 71: buffer portion
31: fixing fitting (metal member)
41: terminal fitting (metal member)

1. A circuit device comprising a circuit board, a connector fixed to the circuit board, and a resin portion covering the circuit board and the connector,
wherein a buffer portion formed from a material having elasticity is interposed between the circuit board and the connector, between the circuit board and the resin portion, or between the connector and the resin portion.

2. The circuit device according to claim 1, wherein the connector comprises a connector housing and a metal member fixed to the connector housing and the circuit board, and the buffer portion is interposed between the metal member and the resin portion.

3. The circuit device according to claim 2, wherein the metal member is a fixing fitting for fixing the connector housing to the circuit board.

4. The circuit device according to claim 2, wherein the metal member is a terminal fitting.
